(19) United States
(12) Patent Application Publication
(10) Pub. No.: US 2022/0178023 A1
(43) Pub. Date: Jun. 9, 2022

(54) METHOD OF FORMING A STRUCTURE INCLUDING SILICON-CARBON MATERIAL, STRUCTURE FORMED USING THE METHOD, AND SYSTEM FOR FORMING THE STRUCTURE

(71) Applicant: ASM IP Holding B.V., Almere (NL)

(72) Inventors: Yoshio Susa, Tokyo (JP); Naoki Umehara, Tokyo (JP); Yu Min Huang, Tokyo (JP)

(21) Appl. No.: 17/543,023

(22) Filed: Dec. 6, 2021

Related U.S. Application Data
(60) Provisional application No. 63/123,091, filed on Dec. 9, 2020.

(51) Int. Cl. C23C 16/455; C23C 16/04; C23C 16/505; C23C 16/56

(52) U.S. Cl. CPC C23C 16/45536; C23C 16/045; C23C 16/56; C23C 16/505; C23C 16/45553

(57) ABSTRACT

Methods and systems for forming a structure including silicon-carbon material and structures formed using the methods or systems are disclosed. Exemplary methods include providing a first gas to the reaction space, providing a silicon-carbon precursor to the reaction space, ceasing a flow of the silicon-carbon precursor to the reaction space, forming a first plasma within the reaction space to thereby deposit silicon-carbon material on a surface of the substrate, and optionally treating the silicon-carbon material with activated species to form treated silicon-carbon material.

### CROSS-REFERENCE TO RELATED APPLICATIONS

This application claims the benefit of and priority to U.S. Provisional Patent Application Ser. No. 63/123,091 filed Dec. 9, 2020, the disclosure of which is hereby incorporated by reference in its entirety.

### FIELD OF INVENTION

The present disclosure generally relates to methods of forming structures suitable for use in the manufacture of electronic devices. More particularly, examples of the disclosure relate to methods of forming structures that include a silicon-carbon material layer, to structures including such layers, and to systems for performing the methods and/or forming the structures.

### BACKGROUND OF THE DISCLOSURE

During the manufacture of devices, such as semiconductor devices, it is often desirable to fill features (e.g., trenches or gaps) on the surface of a substrate with insulating or dielectric material. Because of its high etch selectivity with regard to other materials, such as silicon oxide, silicon-carbon material may be desirable to use in a variety of applications.

Unfortunately, typical silicon-carbon material deposition techniques can result in several voids forming in the deposited silicon-carbon material, especially when the silicon-carbon material is deposited using plasma-assisted techniques.

Accordingly, improved methods for forming structures, particularly for methods of filling gaps on a substrate surface with silicon-carbon material, which mitigate void formation in the silicon-carbon material and/or provide desired silicon-carbon material properties, are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming structures (sometimes referred to herein as film structures) suitable for use in the formation of electronic devices. While the ways in which various embodiments of the present disclosure address drawbacks of prior methods and structures are discussed in more detail below, in general, exemplary embodiments of the disclosure provide improved methods for forming structures that include silicon-carbon material, structures including the silicon-carbon material, and systems for performing the methods and/or forming the structures. The methods described herein can be used to fill features on a surface of a substrate.

In accordance with various embodiments of the disclosure, methods of forming a structure—e.g., methods of filling a patterned recess on a surface of a substrate—are provided. Exemplary methods include providing a substrate comprising the patterned recess within a reaction space, providing a first gas to the reaction space, providing a silicon-carbon precursor to the reaction space, ceasing a flow of the silicon-carbon precursor to the reaction space, and forming a first plasma within the reaction space to thereby deposit silicon-carbon material on a surface of the substrate. In accordance with examples of these embodiments, a flow of the silicon-carbon precursor is ceased prior to forming the first plasma. In accordance with other examples, the first plasma can be continuous through a plurality of deposition steps and/or a plurality of deposition and treatment steps, described in more detail below. The first gas can include, for example, one or more of Ar, He, NH₃, N₂ and H₂. Exemplary methods can additionally include a step of providing a second gas to the reaction chamber. The second gas comprises one or more of Ar, He, NH₃, N₂ and H₂. The first gas and the second gas can be different gases. As set forth in more detail below, various steps of providing the silicon-carbon precursor, providing a first gas, providing a second gas, and forming a plasma can overlap. Exemplary methods can also include a step of treating the silicon-carbon material; the step of treating can include providing the first gas to the reaction chamber during the step of forming the first plasma and/or during a step of forming a second plasma. A chemical formula of the silicon-carbon precursor can be represented by the formula SiₐC_{b}H_{c}N_{d}, where a is a natural number, b is a natural number, c is a natural number and d is 0 or a natural number. As further set forth below, various properties of the silicon-carbon material, such as etch rate, density, composition, and the like, can be manipulated by changing one or more of the first gas, the second gas, and/or another process parameter.

In accordance with further exemplary embodiments of the disclosure, a structure is formed, at least in part, according to a method described herein. The structure can include silicon-carbon material and/or treated silicon-carbon material.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a timing sequence in accordance with exemplary embodiments of the disclosure without an additional plasma treatment step.

FIG. 3 illustrates another timing sequence in accordance with exemplary embodiments of the disclosure with a plasma treatment step.

FIG. 4 illustrates yet another timing sequence in accordance with exemplary embodiments of the disclosure with a plasma treatment step.

FIG. 5 illustrates transmission electron microscopy images and properties of silicon-carbon material in accordance with exemplary embodiments of the disclosure, depending on process sequence as shown in FIGS. 2, 3 and 4.

FIG. 6 illustrates another timing sequence in accordance with examples of the disclosure.

FIG. 7 illustrates scanning transmission electron microscopy images of silicon-carbon material in accordance with exemplary embodiments of the disclosure, depending on a type of precursor.

FIG. 8 illustrates a reactor system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of depositing materials, to methods of forming structures, to structures formed using the methods, and to systems for performing the methods and/or forming the structures. By way of examples, the methods described herein can be used to fill features, such as gaps (e.g., trenches, vias, or spaces between protrusions) on a surface of a substrate with silicon-carbon material. The terms gap and recess can herein be used interchangeably.

To mitigate void and/or seam formation during a gap-filling process, deposited silicon-carbon material can be initially flowable and flow within the gap to fill the gap. The initially-flowable material can then harden. As described below, in at least some cases, the hardened silicon-carbon material can be treated—e.g., to densify the material and/or increase an etch resistance of the silicon-carbon material. As further described below, various silicon-carbon material properties can be tuned by adjusting one or more parameters, such as first and/or second gases used during deposition and/or treatment steps.

Exemplary structures described herein can be used in a variety of applications, including, but not limited to, cell isolation in 3D cross point memory devices, self-aligned vias, dummy gates, reverse tone patterns, PC RAM isolation, cut hard masks, DRAM storage node contact (SNC) isolation, and the like.

In this disclosure, “gas” can refer to material that is a gas at normal temperature and pressure, a vaporized solid and/or a vaporized liquid, and may be constituted by a single gas or a mixture of gases, depending on the context. A gas other than a process gas, i.e., a gas introduced without passing through a gas distribution assembly, such as a showerhead, other gas distribution device, or the like, may be used for, e.g., sealing a reaction space, which includes a seal gas, such as a rare gas. In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than a precursor, that activates a precursor, modifies a precursor, or catalyzes a reaction of a precursor; a reactant may provide an element (such as H) to a film matrix and become a part of the film matrix when, for example, power (e.g., radio frequency (RF) power) is applied. In some cases, the terms precursor and reactant can be used interchangeably. The term “inert gas” refers to a gas that does not take part in a chemical reaction to an appreciable extent and/or a gas that excites a precursor (e.g., to facilitate polymerization of the precursor) when, for example, power (e.g., RF power) is applied, but unlike a reactant, it may not become a part of a film matrix to an appreciable extent.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within or on at least a portion of a layer or bulk material of the substrate. By way of examples, one or more features (e.g., recesses) can have a width of about 10 nm to about 100 nm, a depth or height of about 30 nm to about 1,000 nm, and/or an aspect ratio of about 3.0 to 100.0.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using multiple deposition cycles and/or multiple deposition and treatment cycles.

As used herein, the term “silicon-carbon layer” or “silicon-carbon material” can refer to a layer whose chemical formula can be represented as including silicon and carbon. Layers comprising silicon-carbon material can include other elements, such as one or more of nitrogen and hydrogen.

As used herein, the term “structure” can refer to a partially or completely fabricated device structure. By way of examples, a structure can be a substrate or include a substrate with one or more layers and/or features formed thereon.

As used herein, the term “cyclic deposition process” can refer to a vapor deposition process in which deposition cycles, typically a plurality of consecutive deposition cycles, are conducted in a process chamber. Cyclic deposition processes can include cyclic chemical vapor deposition (CVD) and atomic layer deposition processes. A cyclic deposition process can include one or more cycles that include plasma activation of a precursor, a reactant, and/or an inert gas.

In this disclosure, “continuously” or “continuous” can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

A flowability (e.g., an initial flowability) can be determined as follows:

TABLE 1

| bottom/top | |
|---|---|
| ratio (B/T) | Flowability |
| 0 < B/T < 1 | None |
| 1 ≤ B/T < 1.5 | Poor |
| 1.5 ≤ B/T < 2.5 | Good |
| 2.5 ≤ B/T < 3.5 | Very good |
| 3.5 ≤ B/T | Extremely good |

where B/T refers to a ratio of thickness of film deposited at a bottom of a recess to thickness of film deposited on a top surface where the recess is formed, before the recess is filled. Typically, the flowability is evaluated using a wide recess having an aspect ratio of about 1 or less, since generally, the higher the aspect ratio of the recess, the higher the B/T ratio becomes. The B/T ratio generally becomes higher when the aspect ratio of the recess is higher. As used herein, a “flowable” film or material exhibits good or better flowability.

Flowability of film can be temporarily obtained when a volatile silicon-carbon precursor, for example, is polymerized by a plasma and deposits on a surface of a substrate, wherein the gaseous precursor is activated or fragmented by energy provided by plasma gas discharge, so as to initiate polymerization. The resultant polymer material can exhibit temporarily flowable behavior. When a deposition step is complete and/or after a short period of time (e.g., about 3.0 seconds), the film may no longer be flowable, but rather becomes solidified, and thus, a separate solidification process may not be employed.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

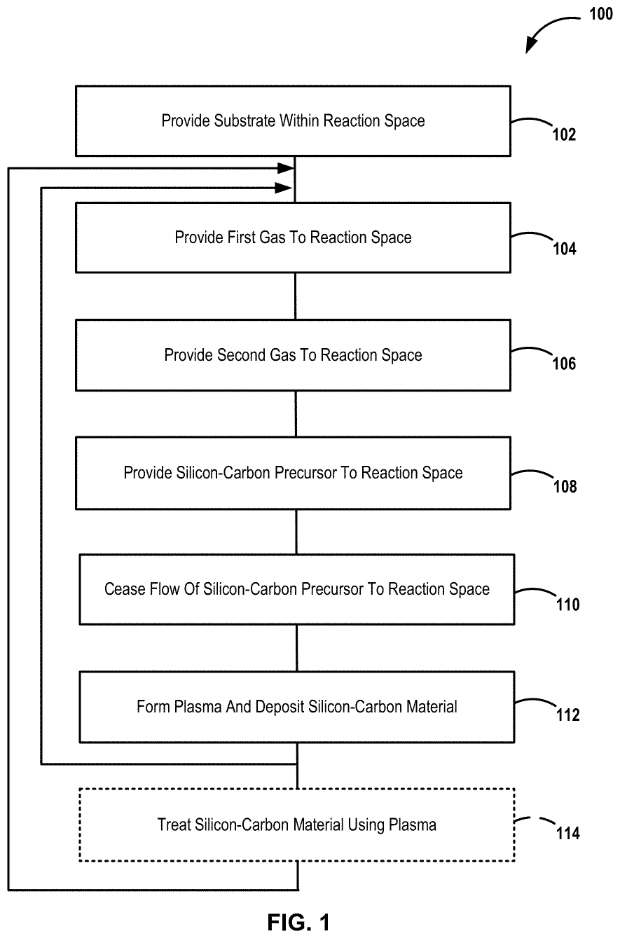

Turning now to the figures, FIG. 1 illustrates a method 100 in accordance with examples of the disclosure. Method 100 can be used to fill one or more patterned recesses on a surface of a substrate. Method 100 can be or include a plasma enhanced chemical vapor deposition (PECVD) process or plasma enhanced atomic layer deposition (PEALD) process or a combination of PECVD and PEALD processes. In some cases, method 100 can be a cyclical deposition process. Method 100 can be used to form silicon-carbon material having an etch selectivity relative to silicon oxide (e.g., SiO₂) of greater than 50 and/or an etch selectivity relative to silicon nitride (e.g., Si₃N₄) of greater than 20.

As illustrated, method 100 includes the steps of providing a substrate within a reaction space (step 102), providing a first gas to the reaction space (step 104), providing a second gas to the reaction space (step 106), providing a silicon-carbon precursor to the reaction space (step 108), ceasing a flow of the silicon-carbon precursor to the reaction space (step 110), and forming a first plasma within the reaction space to thereby deposit silicon-carbon material on a surface of the substrate (step 112). In accordance with particular examples of the disclosure, the substrate includes one or more features, such as recesses. Method 100 can also include a (e.g., plasma) treatment step (step 114).

During step 102, a substrate is provided into a reaction space of a gas-phase reactor. In accordance with examples of the disclosure, the reaction space can form part of a cyclical deposition reactor, such as an atomic layer deposition (ALD) (e.g., PEALD) reactor or chemical vapor deposition (CVD) (e.g., PECVD) reactor. Various steps of methods described herein can be performed within a single reaction chamber or can be performed in multiple reaction chambers, such as reaction chambers of a cluster tool.

During step 102, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be less than or equal to 100° C. (e.g., about 23° C. to about 100° C.). A pressure within the reaction chamber can be from about 200 Pa to about 1,250 Pa.

During step 104, a first gas comprising one or more gases, such as one or more of argon (Ar), helium (He), ammonia (NH₃), nitrogen (N₂), and hydrogen (H₂), separately or any mixture thereof, is provided to the reaction space. By way of particular examples, the first gas is or includes hydrogen. A flowrate of the first gas to the reaction chamber during this step can be from about 200 sccm to about 3,000 sccm.

During step 106, a second gas comprising one or more gases, such as one or more of argon (Ar), helium (He), ammonia (NH₃), nitrogen (N₂), and hydrogen (H₂), separately or any mixture thereof, is provided to the reaction space. The second gas can be different from the first gas. For example, at least one gas in the first and second gases can be different. By way of particular examples, the second gas is or includes argon and/or helium. A mixture of the argon and helium can range from about 0 to about 50 vol. % argon and/or helium. A flowrate of the second gas to the reaction space during this step can be from about 10 sccm to about 2,000 sccm. As described in more detail below, the second gas can be used to facilitate ignition of a plasma within the reaction space, to purge reactants and/or byproducts from the reaction chamber, and/or be used as a treatment gas. In accordance with various examples of the disclosure, step 104 and step 106 can overlap, at least in part.

During step 108, a precursor for forming a layer of silicon-carbon material is introduced into the reaction space. Exemplary silicon-carbon precursors include compounds represented by the formula SiₐC_{b}H_{c}N_{d}, where a is a natural number, b is a natural number, c is a natural number and d is 0 or a natural number. For example, a can range from 1-5, b can range from 1-20, c can range from 1-40, and/or d can range from 0-5. The silicon-carbon precursor can include a chain or cyclic molecule having one or more carbon atoms, one or more silicon atoms, and one or more hydrogen atoms, such as molecules represented by the formula above. By way of particular examples, the precursor can be or include one or more cyclic (e.g., aromatic) structures and/or compounds having at least one double bond.

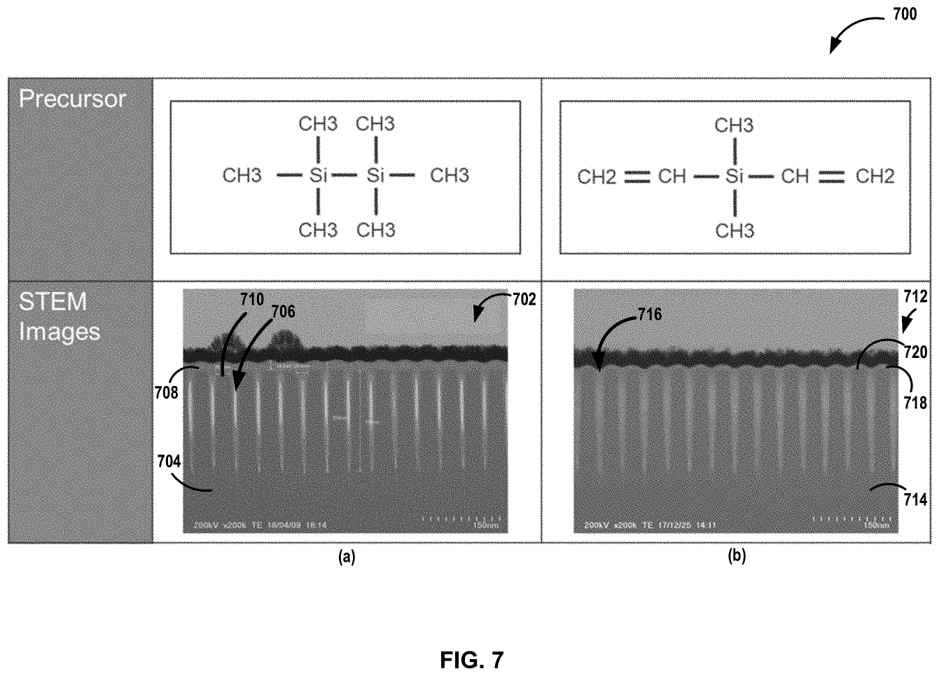

With momentary reference to FIG. 7, (a) illustrates a structure 702 that includes a substrate 704, having gaps 706 formed therein, and a silicon-carbon layer 708 overlying a surface 710 of substrate 704. In FIG. 7, (b) illustrates a structure 712 that includes a substrate 714, having gaps 716 formed therein, and a silicon-carbon layer 718 overlying a surface 720 of substrate 714. The deposition conditions for structures 702 and 712 were the same, except the precursor used to form structure 702 was hexamethyldisilane and the precursor used to form structure 712 was dimethyldivinylsilane (DMDVS). Structure 712 has fewer voids within silicon-carbon layer 718, compared to layer 708 of structure 702, suggesting that use of precursors with at least one carbon (e.g., carbon-carbon) double bond may be beneficial for filling recesses, while mitigating any void formation. Thus, in accordance with examples of the disclosure, the silicon-carbon precursor comprises one or more double bonds.

In accordance with some examples of the disclosure, a chemical formula of the silicon-carbon precursor can be represented by the formula:

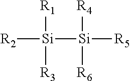

where R₁-R₆ are independently selected from (C1-C10) alkyl, alkene, or aryl groups and H. By way of particular example, each of R₁-R₆ can include a methyl group as illustrated by the following chemical formula.

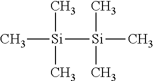

In accordance with other examples of the disclosure, a chemical formula of the silicon-carbon precursor can be represented by the formula:

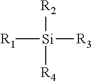

where R₁-R₄ are independently selected from (e.g., C1-C10) alkyl, alkene, or aryl groups and H.

For example, the chemical formula can be represented by

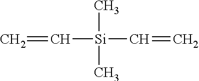

A flowrate of the silicon-carbon precursor from a silicon-carbon precursor source to the reaction chamber can vary according to other process conditions. By way of examples, the flowrate can be from about 100 sccm to about 3,000 sccm. Similarly, a duration of each step of providing a silicon-carbon precursor to the reaction chamber can vary, depending on various considerations. By way of examples, the duration can range from about 1.0 seconds to about 35.0 seconds.

During step 110, a flow of the silicon-carbon precursor to the reaction space is decreased or ceased. During a period following step 110, a concentration of the silicon-carbon precursor within the reaction space can decrease. In some cases, a flow of the silicon-carbon precursor may be reduced and not entirely shut off for various steps.

During step 112, e.g., after step 110, a plasma can be formed. Alternatively, the plasma can form before steps 108 and 110. The plasma can be a direct plasma. A power used to ignite and maintain the plasma can range from about 50 W to about 800 W. A frequency of the power can range from about 0.4 MHz to about 27.12 MHz. At the end of step 112, the plasma may cease—e.g., by reducing or extinguishing a power used to produce a plasma.

During step 112, the silicon-carbon precursor is converted into the initially viscous material using excited species. The initially viscous silicon-carbon material can flow into the at least one recess and can become silicon-carbon material—e.g., through further reaction with excited species. The silicon-carbon material can become solid or substantially solid.

One or more of steps 104-112 can be repeated to form silicon-carbon material of desired thickness.

As noted above, method 100 can also include a treatment step 114. Treatment step 114 can be used to densify the silicon-carbon material. Step 114 can include, for example, treating the silicon-carbon material with activated species to form treated silicon-carbon material. Step 114 can include forming species from, for example, the second gas provided during step 106. A power used to form the plasma during step 114 can range from about 50 W to about 800 W; a frequency of the power can range from about 0.4 MHz to about 27.12 MHz.

In accordance with exemplary aspects of the disclosure, during step 114, activated species are formed by using a plasma (e.g., radio frequency and/or microwave plasma). A direct plasma and/or a remote plasma can be used to form the activated species. In some cases, a gas (e.g., the second gas) can be continuously flowed to the reaction space during one or more steps and activated species can be periodically formed by cycling the power used to form the plasma. A temperature within a reaction chamber during step 114 can be less than or equal to 100° C. A pressure within a reaction chamber during the species formation for treatment can be from about 300 Pa to 2,000 Pa. The species formation for treatment step can be formed in the same reaction chamber used for one or more or other steps or can be a separate reaction chamber, such as another reaction chamber of the same cluster tool. Further, as illustrated, method 100 can include a repeat loop that includes steps 104-114.

As noted above and elsewhere herein, steps of methods described herein can overlap and need not be performed in the order noted above. Further, in some cases, various steps or combinations of steps can be repeated one or more times prior to a method proceeding to the next step.

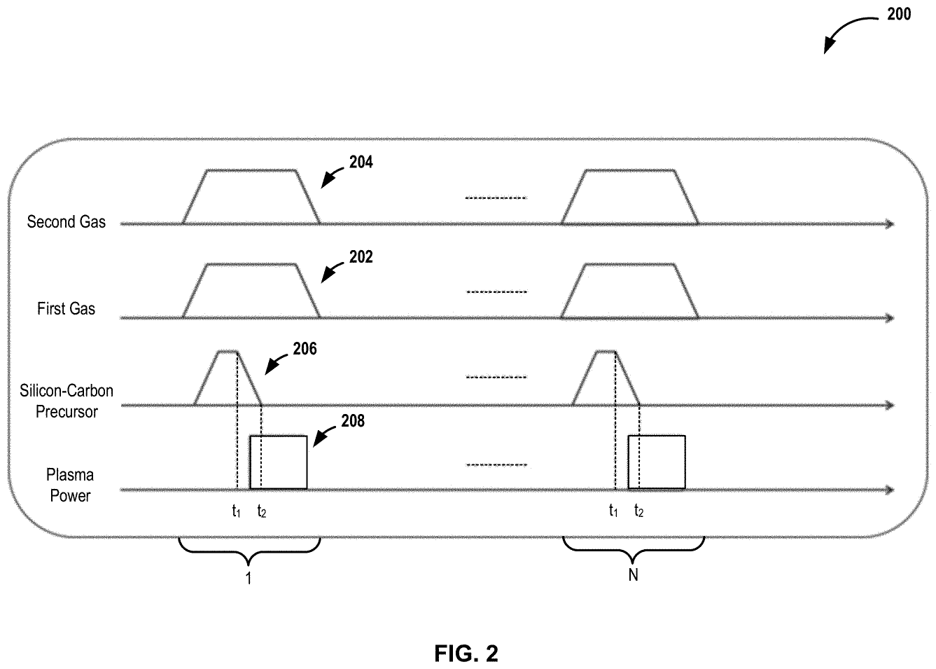

FIGS. 2-4 and 6 illustrate examples of pulse timing sequences for methods in accordance with exemplary embodiments of the disclosure. For example, timing sequences illustrated in FIGS. 2-4 and 6 can be used in connection with method 100.

FIGS. 2-4 and 6 schematically illustrate first gas, second gas, silicon-carbon precursor, and plasma power pulses, where gases and/or plasma power are provided to a reactor system or reaction space for a pulse period. The width of the pulses may not necessarily be indicative of an amount of time associated with each pulse; the illustrated pulses can illustrate relative start times and/or end times of the various pulses. Similarly, a height may not necessarily be indicative of a specific amplitude or value, but can show relatively high and low values. Process conditions for each pulse period can be as described above in connection with corresponding steps of method 100. The examples below are merely illustrative and are not meant to limit the scope of the disclosure or claims.

FIG. 2 illustrates a timing sequence 200 in accordance with examples of the disclosure. Timing sequence 200 includes a plurality of silicon-carbon material deposition and treatment cycles 1-N. In accordance with examples of these embodiments, N can range from about 1 to about 50.

In the example illustrated in FIG. 2, a first gas is provided to the reaction space for a pulse period 202 and a second gas is provided to the reaction chamber for a pulse period 204. Pulse period 202 and/or 204 can range from about 5.0 to about 100.0 seconds and can be the same or different and/or can vary from deposition cycle to deposition cycle.

After pulse period 202 and/or 204 is initiated, a silicon-carbon precursor is provided to the reaction chamber for a pulse period 206. Pulse period 206 can range from, for example, about 1.0 seconds to about 35.0 seconds. Each pulse period 206 can be the same or vary in time. As illustrated, pulse periods 202, 204, and 206 can overlap. For example, pulse period 206 can start after pulse period 202 and/or 204 and can end prior to pulse period 202 and/or 204.

After the flow of the silicon-carbon precursor to the reaction chamber has ceased at t1, power to form a plasma is provided for a pulse period 208. A power (e.g., applied to electrodes) during pulse period 208 can range from about 100 W to about 800 W, or as otherwise noted herein. A frequency of the power can range from about 0.4 MHz to about 27.12 MHz, or as otherwise noted herein.

Pulse period 206 can end at t2, wherein most or substantially all, e.g., 90 percent or more, of the silicon-carbon precursor present at t1 is removed from the reaction space. Pulse period 208 can begin prior to t2 and after t1. Thus, in the illustrated example, the first gas, the second gas, and the silicon-carbon precursor are within the reaction chamber when the plasma is ignited/formed at the beginning of pulse period 208. Pulse period 208 can range from, for example, about 1.0 seconds to about 30.0 seconds. Each pulse period 208 can be the same or vary in time.

As illustrated in this example, pulse period 202 and pulse period 204 may begin and/or cease at about or substantially the same time (e.g., within 10, 5, 2, 1, or 0.5 percent of each other). Once the flow of the silicon-carbon precursor to the reaction chamber has ceased, the silicon-carbon precursor can begin to be purged from reaction space for a purge period or purge pulse using the first and/or second gas. The purge can be further assisted by way of a vacuum pump and can continue after steps 202 and/or 204. The purge period can range from, for example, about 5.0 seconds to about 30.0 seconds. Each purge period can be the same or vary in time.

Timing sequence 200 can also include a treatment step, which can begin at about t2 and end at the end of plasma pulse 208. In the illustrated example, both the first gas and the second gas are provided during the treatment step. In other examples, only the second gas may be provided during the treatment step.

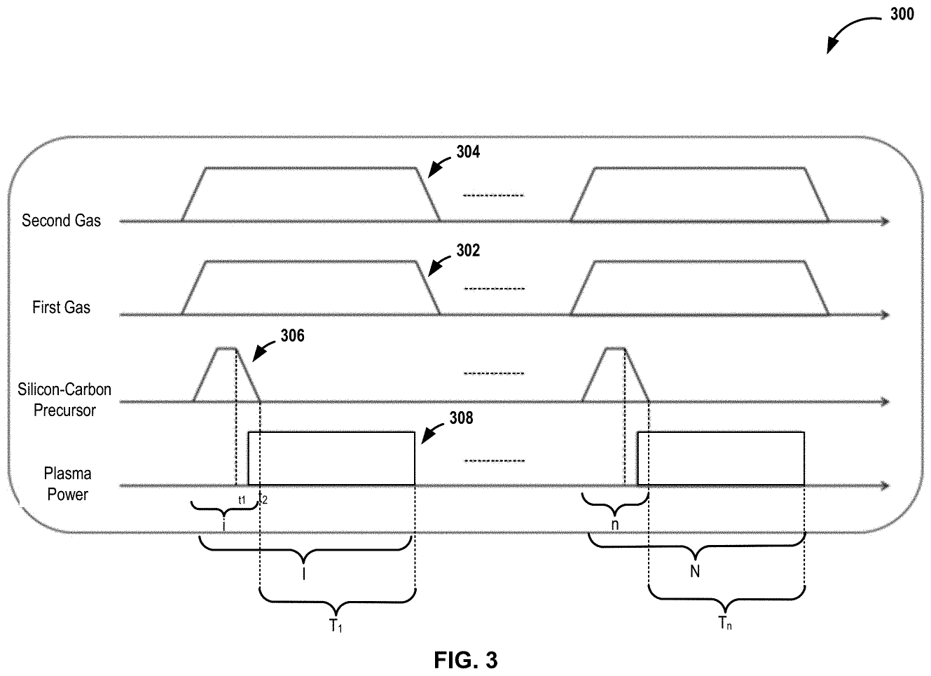

FIG. 3 illustrates another timing sequence 300 in accordance with examples of the disclosure. Timing sequence 300 is similar to timing sequence 200, except the treatment step/pulse period in at least one deposition cycle is longer than the treatment pulse period of timing sequence 200.

Timing sequence 300 includes a plurality of silicon-carbon material deposition cycles i . . . n. In addition, timing sequence 300 includes treatment steps T1 . . . Tn, which, together with a deposition step, are represented by deposition and treatment step or cycle 1 . . . N. In accordance with examples of these embodiments, n can range from about 1 to about 50 and N can range from about 1 to about 50.

Timing sequence 300 can include supplying a first gas and a second gas—e.g., continuously—to the reaction chamber during one or more deposition and treatment steps 1 . . . N. In the illustrated example, the first gas is provided to the reaction chamber for a pulse period 302 and the second gas is provided to the reaction chamber for a pulse period 304. Pulse periods 302 and 304 can overlap. For example, pulse periods 302 and 304 can begin and/or end at about the same time. Pulse periods 302 and/or 304 can begin prior to pulse periods 306 and/or 308 described below and can continue until at least an end of pulse period 308. The first and/or second gas can be used to facilitate purging the reaction space between deposition steps and/or deposition and treatment steps and/or can be used to facilitate plasma formation during deposition and/or treatment of silicon-carbon material.

Pulse period 302 and/or 304 can be the same or similar to pulse period 202 and 204 described above; pulse periods 302, 304 can range from about 10.0 to about 100.0 seconds and can be the same or different and/or can vary from treatment and deposition cycle to treatment and deposition cycle.

During pulse period 306, a silicon-carbon precursor is provided to the reaction space for a pulse. Pulse period 306 can range from, for example, about 1.0 seconds to about 5.0 seconds. Similar to pulse period 206, pulse period 306 can cease at t1 and the silicon-carbon precursor can be substantially removed at t2.

After the flow of the silicon-carbon precursor to the reaction chamber has ceased at t1, power to form a plasma is provided for a pulse period 308. Thus, the flow of the silicon-carbon precursor is ceased prior to a plasma being ignited/formed.

A deposition step can start when the plasma is ignited and end when the silicon-carbon precursor is substantially dissipated from the reaction space at t2.

A treatment step (T1-Tn) can be performed using a remainder of pulse 308. In this case, the treatment step can begin at t2 and end at the end of pulse 308.

A power level and pressure within the reaction chamber can be as described above in connection with pulse 208. Pulse period 308 can range from, for example, about 1 seconds to about 30 seconds. Each pulse period 308 can be the same or vary in time.

After pulse period 308, the reaction chamber can be purged for a pulse period. The purge pulse period can range from, for example, about 10 seconds to about 70 seconds. Each purge pulse period can be the same or vary in time.

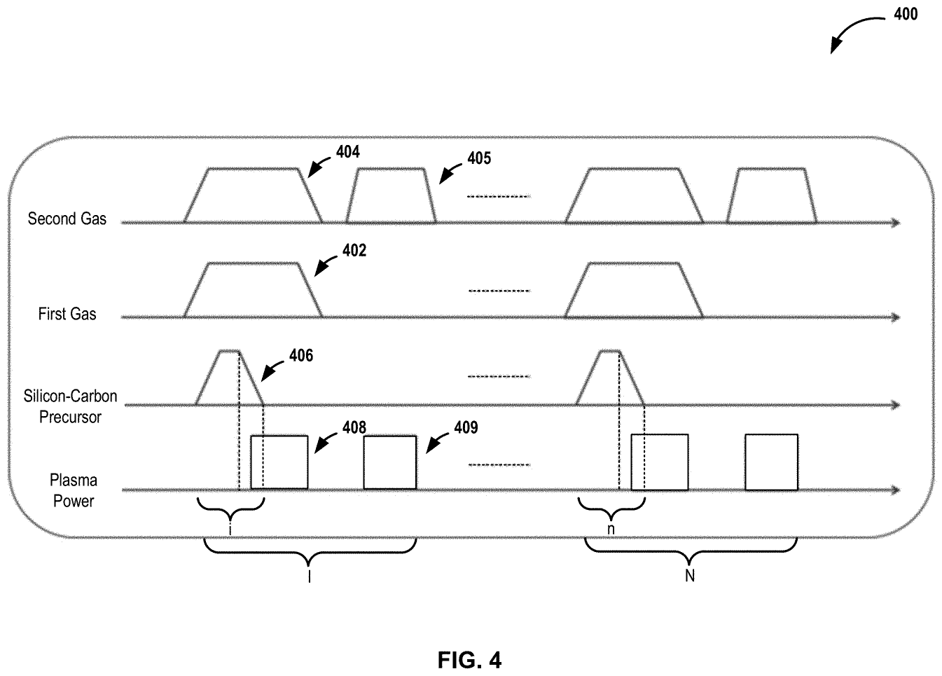

FIG. 4 illustrates another timing sequence 400 in accordance with additional examples of the disclosure. Timing sequence 400 is similar to timing sequence 300, except timing sequence 400 includes separate deposition and treatment plasma pulses 408 and 409, which do not overlap, rather than a continuous plasma pulse 308. In addition, timing sequence 400 includes separate second gas pulses 404 and 405, rather than a continuous pulse 304. And, sequence 400 does not include providing the first gas during a treatment step/pulse period.

Timing sequence 400 includes a plurality of silicon-carbon material deposition cycles i . . . n. In addition, timing sequence 400 includes treatment steps, which, together with a deposition step, are represented by deposition and treatment step or cycle 1 . . . N. In accordance with examples of these embodiments, n can range from about 1 to about 50 and N can range from about 1 to about 50.

First gas pulse 402 and second gas pulse 404 can be the same or similar to first gas pulse 202 and second gas pulse 204 described above in connection with FIG. 2. First gas pulse 402 and second gas pulse 404 can overlap, can start and/or end at about the same time, and/or can be about the same duration.

Similarly, silicon-carbon precursor pulse 406 can be the same or similar to silicon-carbon precursor pulse 206 or 306. And, plasma pulse 408 can be the same or similar to plasma pulse 208.

Second gas pulse 405 can range from about 1.0 to about 90.0 seconds. The flowrate of the second gas can be as described in connection with pulses 204, 304. As illustrated in FIG. 4, second gas pulse 405 can begin after plasma pulse 408 ends and prior to plasma pulse 409 beginning. Second gas pulse 405 can end after plasma pulse 409.

Conditions for plasma pulse 409 can be the same or similar to the conditions for plasma pulse 308 and/or 408. Alternatively, a power level can be raised during plasma pulse period 408, compared to the power used during plasma pulse period 408. A power applied during pulse period 409 can range from about 100 W to about 800 W. A frequency of the power can range from about 0.4 MHz to about 27.12 MHz.

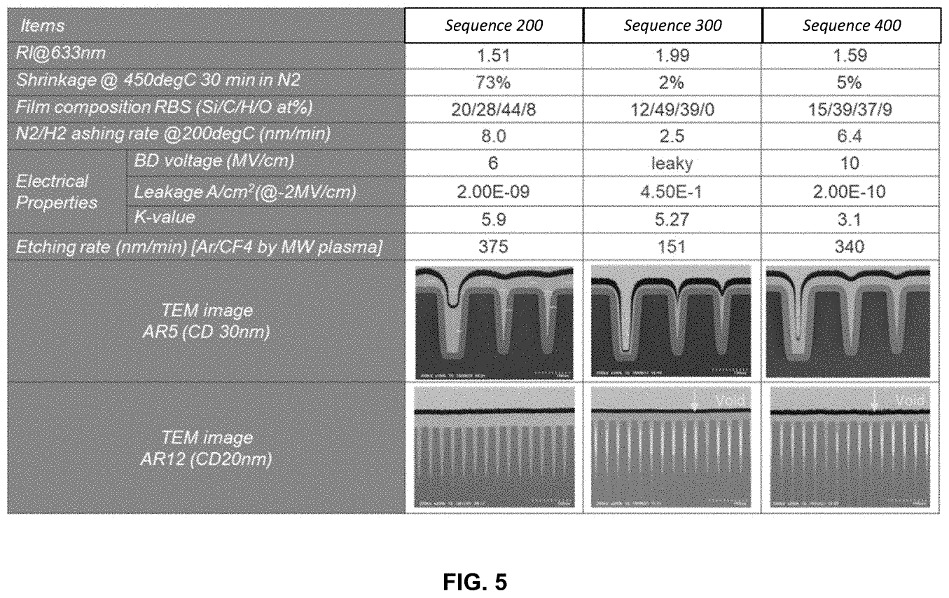

FIG. 5 illustrates exemplary transmission electron microscopy (TEM) images of features filled using timing sequences 200, 300, and 400. The following process conditions were used.

| | | Exemplary |
|---|---|---|
| | Sequence 200/300/400 | Range |
| Silicon-carbon | Dimethyldivinylsilane | See above |
| precursor | | |
| First gas | Hydrogen (0-50%) | One or more |
| | Ar or He (50-100%) | of Ar, He, NH₃, |
| | | N₂ and H₂ |
| Second gas | Hydrogen (0-50%) | One or more |
| | Ar or He (50-100%) | of Ar, He, NH₃, |
| | | N₂ and H₂ |
| Substrate temperature | Same as right | 23-100° C. |
| Reaction space | Same as right | 300 Pa to |
| pressure for deposition | | 2,000 Pa. |
| Reaction space | Same as right | 300 Pa to |
| pressure for treatment | | 2,000 Pa. |
| Plasma power for | 50 to 500 W | Same as left |
| deposition | | |
| Plasma power for | 50 to 3,000 W | Same as left |
| deposition | | |
| Deposition pulse | ON_0.5 to 5.0 seconds | Same as left |
| period | OFF_3.0 to 10.0 seconds | |
| Treatment pulse | ON_1.0 to 90.0 seconds | Same as left |
| period | OFF_3.0 to 150.0 seconds | |

As illustrated in FIG. 5, silicon-carbon material deposited using sequence 300 and sequence 400 exhibited less shrinkage and lower etch rate, compared to silicon-carbon material deposited using timing sequence 200 (with no or a relatively short treatment step). Further, the use of a second gas (e.g., hydrogen) in addition to a first gas during a treatment step produced silicon-carbon material with higher etch resistance, compared to silicon-carbon material treated with only the second gas. Thus, treatment time and/or gas (first and/or second gas) provided during a treatment pulse can be manipulated to manipulate properties of silicon-carbon material.

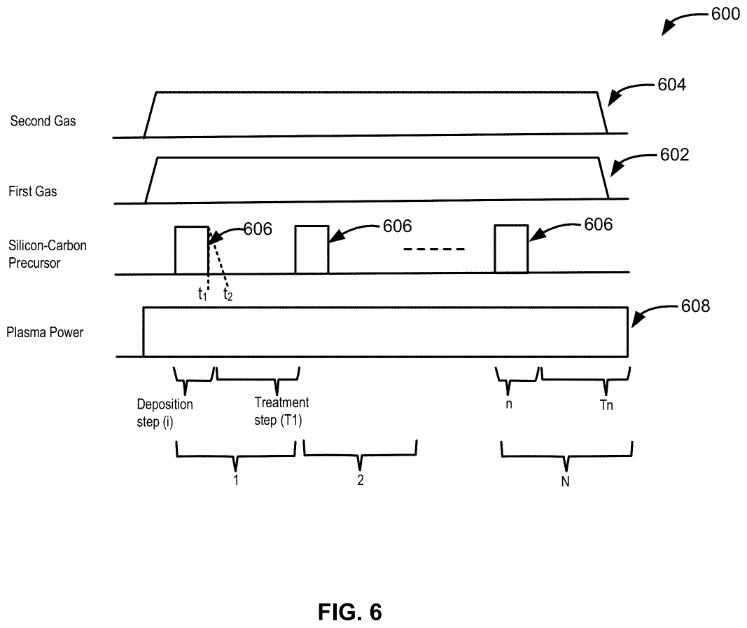

FIG. 6 illustrates another timing sequence 600 in accordance with examples of the disclosure. Timing sequence 600 is similar to timing sequence 200, except that a power plasma step is continuous through one or more deposition and treatment steps.

Timing sequence 600 includes a plurality of silicon-carbon material deposition cycles i . . . n. In addition, timing sequence 600 includes treatment steps T1 . . . Tn, which, together with a deposition step, are represented by deposition and treatment step or cycle 1 . . . N. In accordance with examples of these embodiments, n can range from about 1 to about 200 and N can range from about 1 to about 200.

Timing sequence 600 can include supplying a first gas and a second gas—e.g., continuously—to the reaction chamber during one or more deposition and treatment steps 1 . . . N. In the illustrated example, the first gas is provided to the reaction chamber for a pulse period 602 and the second gas is provided to the reaction chamber for a pulse period 604. Pulse periods 602 and 604 can overlap. For example, pulse periods 602 and 604 can begin and/or end at about the same time. Pulse periods 602 and/or 604 can begin prior to pulse periods 606 and/or 608 described below and can continue until at least an end of pulse period 608. The first and/or second gas can be used to facilitate purging the reaction space between deposition steps and/or deposition and treatment steps and/or can be used to facilitate plasma formation during deposition and/or treatment of silicon-carbon material.

Pulse period 602 and/or 604 can be the same or similar to pulse period 202 and 204 described above; pulse periods 602, 604 can range from about 10.0 to about 100.0 seconds and can be the same or different and/or can vary from treatment and deposition cycle to treatment and deposition cycle.

During pulse period 606, a silicon-carbon precursor is provided to the reaction space for a pulse. Pulse period 606 can range from, for example, about 0.01 seconds to about 10.00 seconds. Similar to pulse period 206, pulse period 606 can cease at t1 and the silicon-carbon precursor can be substantially removed at t2.

Power to form a plasma is provided for a pulse period 608. In the illustrated example, the plasma power can be continuous through a deposition and treatment step or during a plurality of deposition and treatment steps.

In this case, a deposition step can start when the silicon-carbon precursor is provided to the reaction chamber and end when the silicon-carbon precursor is substantially dissipated from the reaction space at t2.

A treatment step (T1-Tn) can be performed using a remainder of pulse 608 (between silicon-carbon precursor pulses 606). In this case, the treatment step can begin at t2 and end at the beginning of a pulse 606.

A power level and pressure within the reaction chamber during sequence 600 can be as described above in connection with pulse 208. Pulse period 608 can range from, for example, about 1 second to about 5,000 seconds.

After pulse period 608, the reaction chamber can be purged for a pulse period. The purge pulse period can range from, for example, about 1 seconds to about 10 seconds.

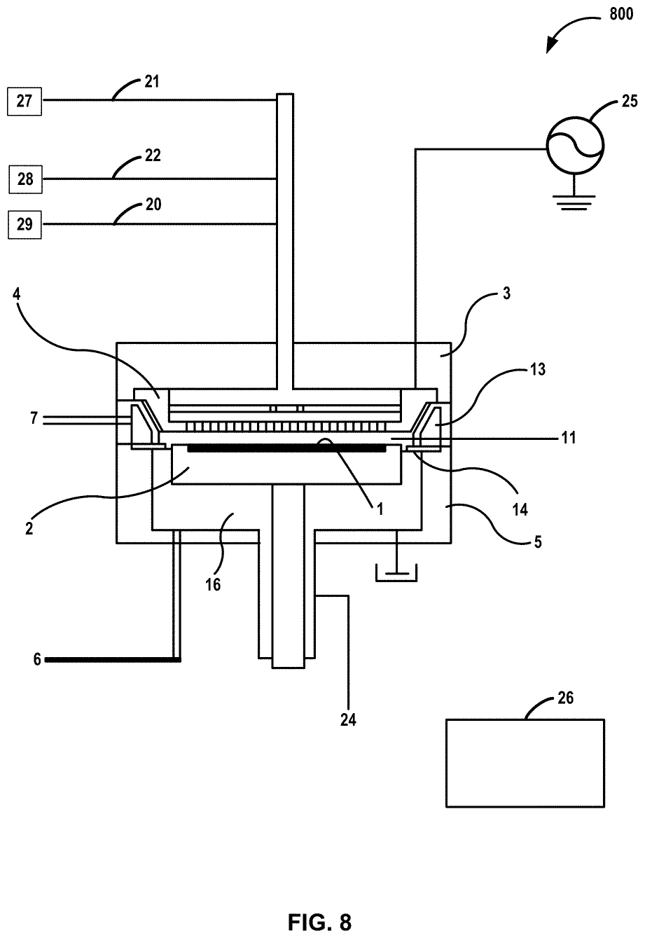

FIG. 8 illustrates a reactor system 800 in accordance with exemplary embodiments of the disclosure. Reactor system 800 can be used to perform one or more steps or sub steps as described herein and/or to form one or more structures or portions thereof as described herein.

Reactor system 800 includes a pair of electrically conductive flat-plate electrodes 4, 2 in parallel and facing each other in the interior 11 (reaction space) of a reaction chamber 3. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. First gas, second gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 800 can include any suitable number of gas lines.

In reaction chamber 3, a circular duct 13 with an exhaust line 7 is provided, through which gas in the interior 11 of the reaction chamber 3 can be exhausted. Additionally, a transfer chamber 5, disposed below the reaction chamber 3, is provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone is provided (a gate valve through which a wafer is transferred into or from the transfer chamber 5 is omitted from this figure). The transfer chamber is also provided with an exhaust line 6. In some embodiments, the deposition and treatment steps are performed in the same reaction space, so that two or more (e.g., all) of the steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching between the main line and the detour line, without substantially fluctuating pressure of the reaction chamber.

A skilled artisan will appreciate that the apparatus includes one or more controller(s) 26 programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of filling a patterned recess on a surface of a substrate, the method comprising the steps of:
providing a substrate comprising the patterned recess within a reaction space;
providing a first gas to the reaction space;
providing a silicon-carbon precursor to the reaction space;
ceasing a flow of the silicon-carbon precursor to the reaction space; and
forming a first plasma within the reaction space to thereby deposit silicon-carbon material on a surface of the substrate.

2. The method of claim 1, wherein the first gas comprises one or more of Ar, He, NH₃, N₂ and H₂.

3. The method of claim 1, further comprising a step of providing a second gas to the reaction chamber.

4. The method of claim 3, wherein the second gas comprises one or more of Ar, He, NH₃, N₂ and Hz, and wherein the first gas differs from the second gas.

5. The method of claim 1, wherein the step of providing the first gas and the step of providing the silicon-carbon precursor overlap.

6. The method of claim 3, wherein the step of providing the first gas and the step of providing the second gas overlap.

7. The method of claim 1, comprising a step of treating the silicon-carbon material, wherein the step of treating comprises providing the first gas to the reaction chamber during the step of forming the first plasma.

8. The method of claim 1, comprising a step of treating the silicon-carbon material, wherein the step of treating comprises providing the second gas to the reaction chamber during a step of forming a second plasma.

9. The method of claim 8, wherein the first plasma and the second plasma do not overlap.

10. The method of claim 1, wherein the method comprises a plasma enhanced chemical vapor deposition (PECVD) process or plasma enhanced atomic layer deposition (PEALD) process or a combination of PECVD and PEALD processes.

11. The method of claim 1, wherein PECVD includes the method of RF pulsing with continuous precursor supply or precursor pulsing with continuous RF supply.

12. The method of claim 1, wherein a chemical formula of the silicon-carbon precursor is represented by the formula SiₐC_{b}H_{c}N_{d}, where a is a natural number, b is a natural number, c is a natural number and d is 0 or a natural number.

13. The method of claim 12, wherein a ranges from 1-5, b ranges from 1-20, c ranges from 1-40, and d ranges from 0-5.

14. The method of claim 1, wherein a chemical formula of the silicon-carbon precursor comprises one or more double bonds.

15. The method of claim 1, wherein a chemical formula of the silicon-carbon precursor is represented by the formula: 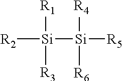
where R₁-R₆ are independently selected from alkyl, alkene, or aryl groups and H.

16. The method of claim 1, wherein a chemical formula of the silicon-carbon precursor is represented by the formula: 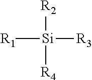
where R₁-R₄ are independently selected from alkyl, alkene, or aryl groups and H.

17. The method of claim 1, wherein the silicon-carbon precursor comprises one or more of:

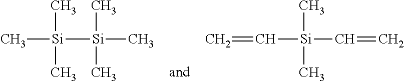

18. The method of claim 1, wherein a temperature within the reaction chamber is less than 100° C.

19. The method of claim 1, wherein a pressure within the reaction chamber is between 300 Pa and 2,000 Pa.

20. The method of claim 3, wherein properties of the silicon-carbon material are manipulated by changing one or more of the first gas and the second gas.

21. The method of claim 1, wherein an etch selectivity of the silicon-carbon material compared to silicon oxide is greater than 50.

22. The method of claim 1, wherein an etch selectivity of the silicon-carbon material compared to silicon nitride is greater than 20.

23. A structure formed according to the method of claim 1.
